(19) United States
(12) Patent Application Publication
(10) Pub. No.: US 2013/0344684 A1
(43) Pub. Date: Dec. 26, 2013

(54) METHODS AND SYSTEMS FOR USING SUBSURFACE LASER ENGRAVING (SSLE) TO CREATE ONE OR MORE WAFERS FROM A MATERIAL

(71) Applicant: Stuart Bowden, Tempe, AZ (US)

(72) Inventor: Stuart Bowden, Tempe, AZ (US)

(21) Appl. No.: 13/922,617

(22) Filed: Jun. 20, 2013

Related U.S. Application Data
(60) Provisional application No. 61/662,327, filed on Jun. 20, 2012.

(51) Int. Cl. H01L 21/263; B23K 26/36

(52) U.S. Cl. CPC H01L 21/2633; B23K 26/365
USPC 438/463; 219/121.68

(57) ABSTRACT

In accordance with some embodiments, a method for using SSLE to create one or more wafers from a material is provided, the method comprising: using a laser light beam to etch pits in the material to create one or more layers of etch pits in a subsurface of the material; and dividing the material into one or more individual wafers with an etch. In accordance with some embodiments, a system for using SSLE to create one or more wafers from a material is provided, the system comprising: a controller for controlling the position of a focal point of a laser light beam with respect to the material and causing an irradiation of the laser light beam at a plurality of focal points; and an etch for splitting the material into the one or more wafers based on the plurality of focal points.

### CROSS-REFERENCE TO RELATED APPLICATION

This application claims the benefit of U.S. Provisional Application No. 61/662,327, filed Jun. 20, 2012, which is hereby incorporated by reference herein in its entirety.

### STATEMENT REGARDING FEDERALLY SPONSORED RESEARCH OR DEVELOPMENT

The invention was made with government support under Grant No. 1041895 awarded by the National Science Foundation. The government has certain rights in the invention.

### TECHNICAL FIELD

The disclosed subject matter relates to methods and systems for using Subsurface Laser Engraving (SSLE) to create one or more wafers from a material.

### BACKGROUND

Silicon solar cells comprise 80% of the worldwide production of photovoltaics (PV) and almost all of this production occurs on watered substrates. Wafers are typically created by slicing blocks of silicon using a wire dicing saw which can not only cause a large amount of the silicon to be wasted, but also uses a cutting fluid that coats the silicon and subsequently needs to be removed.

Other methods for creating wafers, including directly depositing thin silicon layers, cleaving thin substrates, and producing kerfless slices of silicon from an ingot via ion implantation also have limitations.

Accordingly, new processes for producing silicon wafers are desirable.

### SUMMARY

Methods and systems for using SSLE to create one or more wafers from a material are provided. In accordance with some embodiments, a method for using SSLE to create one or more wafers from a material is provided, the method comprising: using a laser light beam to etch pits in the material to create one or more layers of etch pits in a subsurface of the material; and dividing the material into one or more individual wafers with a subsequent etch.

In accordance with some embodiments, the laser light beam has a wavelength between about 1 μm and about 2 μm.

In accordance with some embodiments, the material is transparent to the laser light beam at some intensities and absorbs energy from the laser light beam at other intensities.

In accordance with some embodiments, the laser light beam has an intensity over 1×10⁶ W/cm².

In accordance with some embodiments, the one or more wafers are cut to a thickness between about 10 μm to about 200 μm.

In accordance with some embodiments, the laser creates etch pits between about 10 microns to about 1 mm apart.

In accordance with some embodiments, a system for using SSLE to create one or more wafers from a material is provided, the system comprising: a controller for controlling the position of a focal point of a laser light beam with respect to the material and causing an irradiation of the laser light beam at a plurality of focal points; and an etch for splitting the material into the one or more wafers based on the plurality of focal points.

In accordance with some embodiments, the laser light beam has a wavelength of between about 1 μm to about 2 μm.

In accordance with some embodiments, the material is transparent to the laser light beam at some intensities and absorbs the laser light beam at other intensities.

In accordance with some embodiments, the laser light beam has an intensity over 1×10⁶ W/cm².

In accordance with some embodiments, the controller causes the plurality of focal points to define wafers with thicknesses between about 10 μm to about 200 μm.

In accordance with some embodiments, the controller causes the laser light beam to create etch pits between about 10 microns to about 1 mm apart.

In accordance with some embodiments, the controller causes the laser light beam to create etch pits at more than one depth within a material, for example, through the use of different power levels and/or wavelengths and/or different focal lengths, and/or using multiple scans across a wafer.

### BRIEF DESCRIPTION OF THE DRAWINGS

FIG. 1 shows pits in a silicon block which can occur at the focal point of a laser in accordance with some embodiments.

FIG. 2 is a graph showing Absorption A (%) versus Laser-Intensity (Iₛ) for a laser light beam in accordance with some embodiments.

FIG. 3 is a graph showing Transmission (ratio) versus Optical intensity, W/cm², for an Er-YAG laser and a Ho-YAG laser in accordance with some embodiments.

FIG. 4 shows a laser light beam with subsurface focal point cutting a silicon block into one or more wafers in accordance with some embodiments.

FIG. 5 shows hardware which can be used to control the positioning and focal depth of a laser light beam in accordance with some embodiments.

FIG. 6 is a flow diagram of a process for controlling the positioning and focal depth of a laser light beam in accordance with some embodiments.

### DETAILED DESCRIPTION

Methods and systems for using SSLE to create one or more wafers from a material are provided.

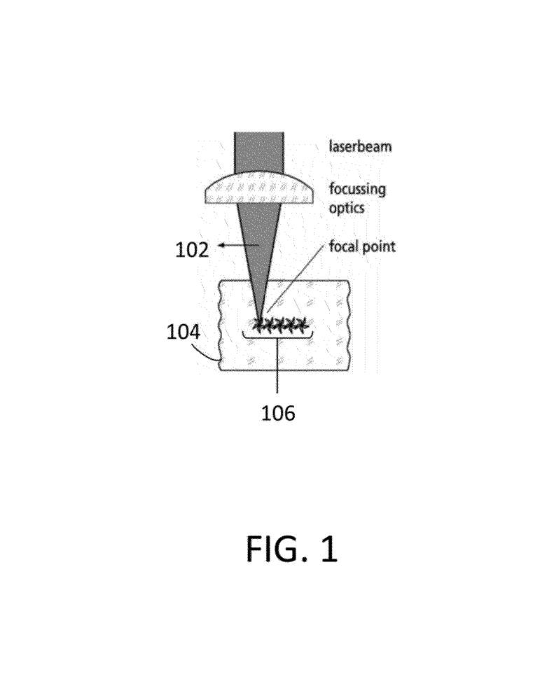

Turning to FIG. 1, in accordance with some embodiments, SSLE can occur by focusing laser light beam 102 within the bulk of an optically transparent material 104 such as silicon. Material 104 can be transparent to the wavelength of laser light beam 102. The intensity of laser light beam 102 at its focal point can be high, which can cause absorption over a small area. As shown in FIG. 1, this absorption can produce a small defect that may appear as a pit 106 in material 104 while leaving the rest of material 104 undamaged. By scanning laser light beam 102 across the surface of a material, such as silicon, as well as varying the focal depth, a 3D array of pits 106 can be created within the material.

Rather than completely cutting through each layer of material 104, small etch pits 106 can be created which can result in layers of weakened material that can then be etched in an anisotropic etch, such as potassium hydroxide (KOH) for silicon materials or any other suitable etch. For example, a silicon block which has been scanned by laser light beam 102 to create a 3D array of pits 106 can be submerged in a container of liquid KOH. The KOH can then etch the silicon at different rates depending on the crystalline plane of the silicon created by laser light beam 102. For other materials, other anisotropic etchants are known and can be used. For example. Gallium Arsenide may be etched using a hydrochloric acid based etching solution.

In accordance with some embodiments, laser light beam 102 and semiconductor material requirements can vary. A variety of laser light beams can be used, such as green, infrared, and/or any other suitable wavelength of laser light beam. A multi-wavelength laser light beam can also be used. One or more of these laser light beams can be used with one or more materials, such as silicon, germanium, silicon carbide, III-V compound semiconductor materials including but not limited to GaAs and InP, II-VI compound semiconductor materials including but not limited to CdTe, glass, crystal gemstones, acrylic, and/or any other suitable material.

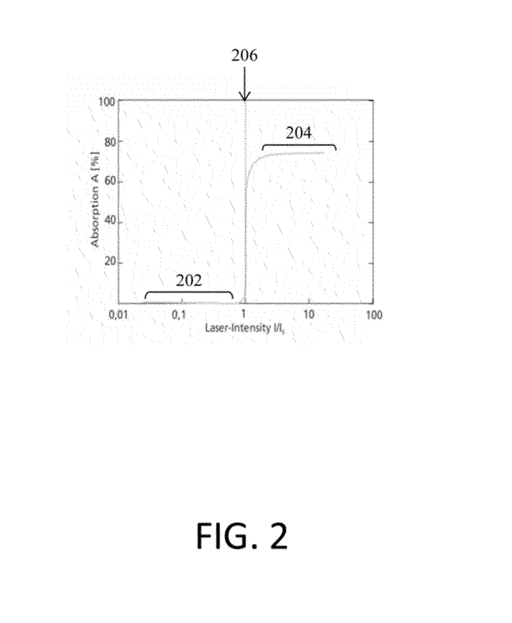

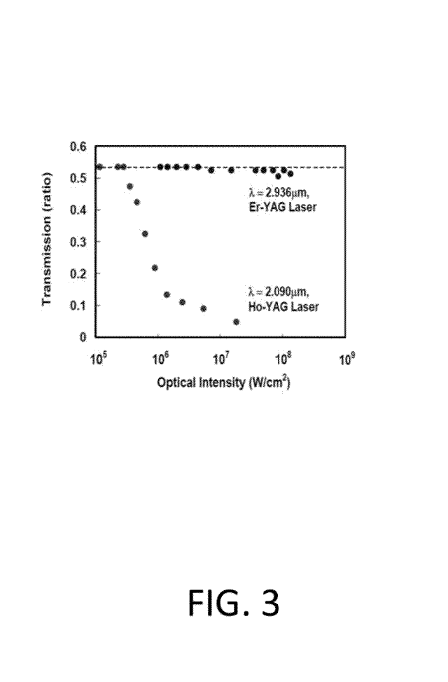

Material 104 can be transparent to laser light beam 102 under some intensities and can absorb laser light beam 102 at other intensities. FIG. 2 is a graph showing Absorption A (%) versus Laser-Intensity (Iₛ) for a laser light beam and water material in accordance with some embodiments. As shown in FIG. 2, material 104 can be transparent to the laser light within a first range of intensities (area 202), and material 104 can absorb the laser light at a second range of intensities (area 204). A transition 206 between these areas can constitute a threshold intensity. Silicon, for example, has a threshold intensity (Iₛ) at 10⁶ W/cm², as shown, for example, in FIG. 3.

The threshold intensity can be a point or range of intensities above which laser light beam 102 is absorbed and below which the semiconductor is transparent. For example, a GaAs (Gallium Arsenide) wafer has a band gap of 1.43 eV (electron volt) and can be cut using a laser with a wavelength of more than 900 nm (nanometer). Tuning the wavelength of the laser can optimize the quality of the cleaved layer.

Material 104 can be matched with SSLE, which can require a non-linear absorption coefficient and a Q-switched laser. A semiconductor such as silicon has a known non-linearity which can be caused by carrier absorption and two-photon processes. There are a variety of lasers with wavelengths between about 1 μm to about 2 μm that can be used in some embodiments (e.g., Silicon waters). For example, a Ho-YAG laser with a wavelength of 2.09 μm exhibits a transition to absorption in Silicon at an optical intensity of 10⁶ W/cm² as shown in FIG. 3. Therefore, tuning the wavelength of laser light can adjust the absorption of laser light by the semiconductor. In the case of silicon, the absorption coefficient of silicon, as an indirect bandgap semiconductor, has a long tail. Silicon can absorb laser light at wavelengths between about 1200 nm and about 3000 nm. Other wavelengths of light can be used for other materials

For example, a laser light beam with a wavelength between about 1 μm to about 2 μm can ablate a series of etch pits beneath a surface of the silicon several centimeters down. The layers of silicon can be cut to a thickness between about 10 μm to about 200 μm with kerf losses limited by the focus of the laser beam (e.g., 20 μm).

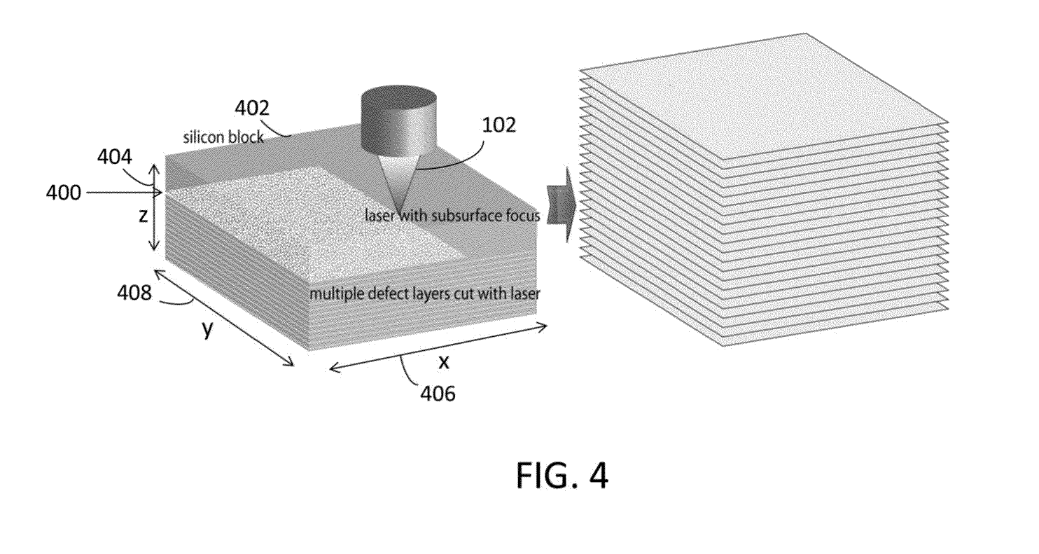

Scanning laser light beam 102 across the surface and varying the focal depth can produce a 3D array of pits 400 within a block of material, as shown in silicon block 402 in FIG. 4. Additionally, scanning from the bottom to the top can focus laser light beam 102 on the succession of layers. The entire block of the material can be patterned with laser light beam 102 in some embodiments.

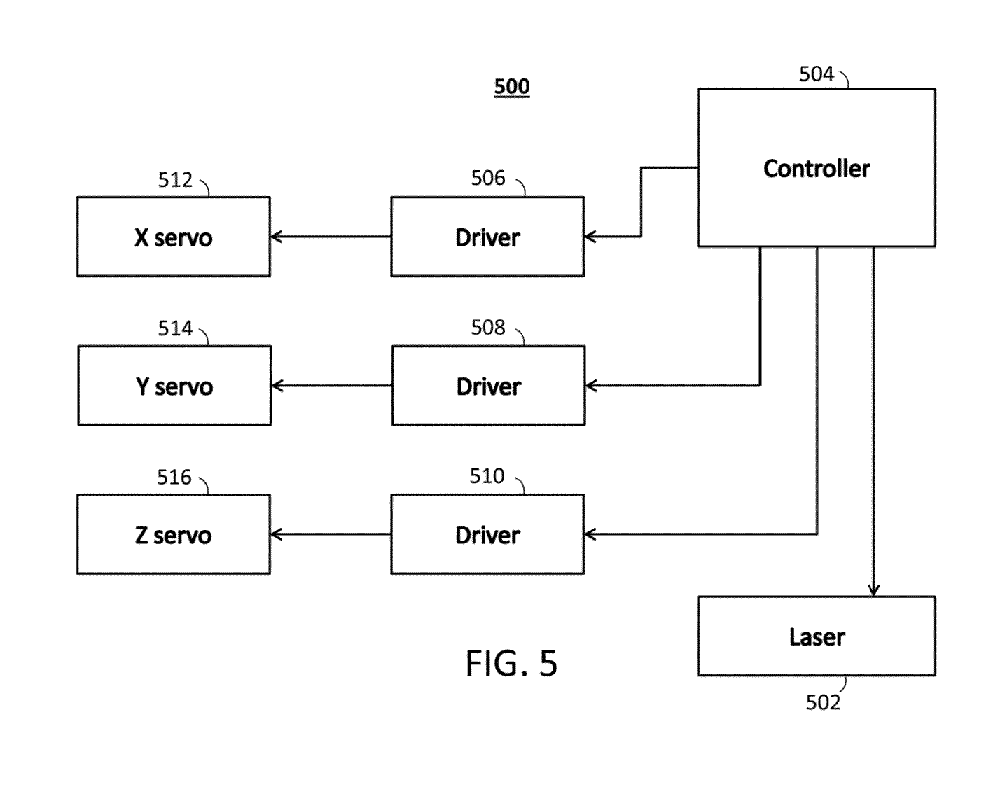

FIG. 5 shows hardware 500 which can be used to pattern a block of material by controlling the position and focal depth of a laser 502. A user can input parameters into controller 504 which can define the thickness and size of the wafers to be cut by laser 502. These parameters can be entered such that by scanning laser 502 across the surface of a block of material, as well as varying the focal depth, an array of pits can be created within block of material.

For example, a parameter can be entered which defines the thickness of a wafer. The thickness can be the distance between layers in z-axis 404, as shown in FIG. 4. Tuning the wavelength of laser 502 can alter the amount of laser light which can be absorbed by the material.

Furthermore, parameters can be entered which can define the size of a wafer. For example, parameters can be entered which can define a width in x-axis 406 and a length in y-axis 408 as shown in FIG. 4. Additionally, parameters can be entered which can be used to scan laser 502 across the block of material a certain width and length and can create etch pits in the block of material a specified distance apart.

Based on one or more parameters entered into controller 504, for width, length, and depth, a signal can be sent to drivers 506, 508, and 510, respectively. Drivers 506, 508, and 510 can then amplify the signals to move x servo 512, y servo 514, and z servo 516 to the appropriate width, length, and focal depth. Controller 504 can then send a signal to trigger laser 502.

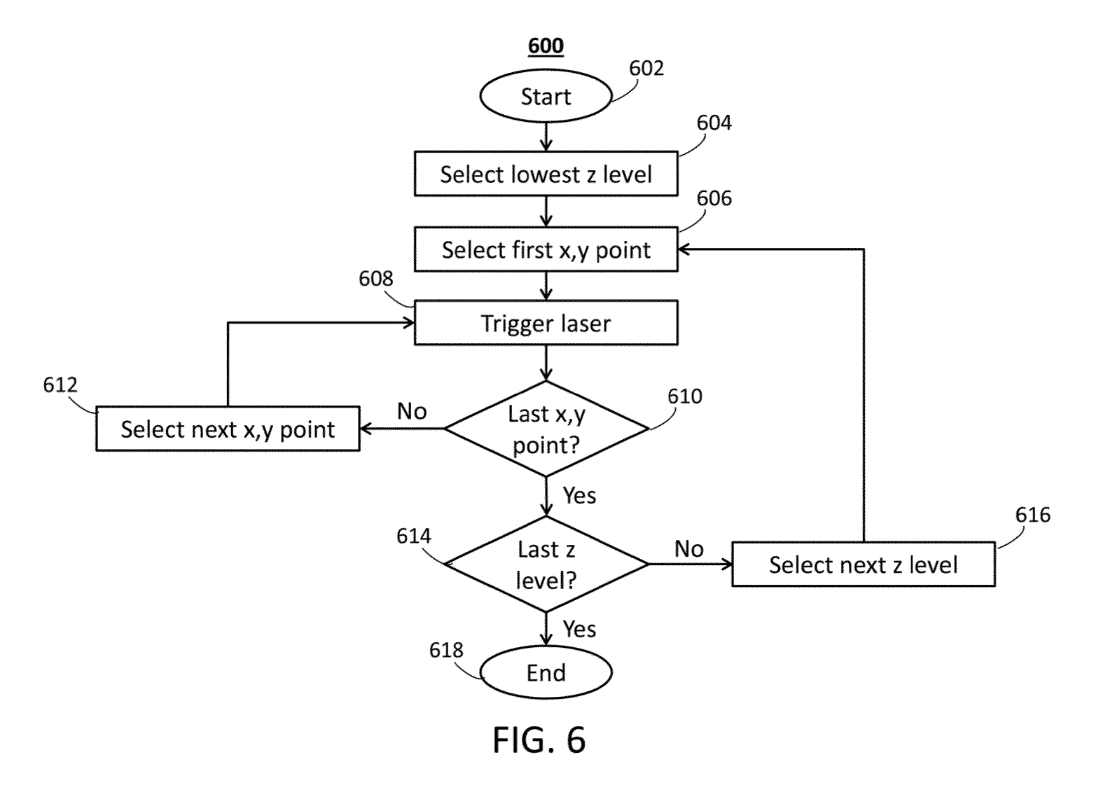

FIG. 6 is a flow diagram of a process for controlling the positioning and focal depth of a laser in accordance with some embodiments. Any suitable mechanism for controlling the positioning and focal depth of a laser can be used in some embodiments. For example, a process such as process 600 of FIG. 6 can be implemented by hardware 500 to control the position and focal depth of a laser in some embodiments.

For example, a set of parameters can be entered at controller 504 which can cause laser 502 to scan the surface of a block of material at varying focal depths to produce a 3D array of pits. Varying the focal depth of laser 502 can create etches beginning at the bottom and ending at the top of a block of material. Scanning the silicon block at each focal depth can pattern the entire block of silicon to produce a succession of layers.

As shown in FIG. 6, after process 600 begins at 602, controller 504 can begin by selecting the lowest z level at 604 and the first x, y point at 606 based on parameters entered by a user. Controller 504 can then send signals to drivers 506, 508, and 510, respectively, which can then, based on the signals, cause the x-servo 512, y-servo 514, and z-servo 516 to move (if necessary) to the appropriate x and y positions and focal depth. Controller 504 can then send a signal to trigger laser 502 at 608.

Controller 504 can then determine if an x, y point is the last coordinate for a particular focal depth (z level). If at 610, controller 504 determines that an x, y point is not the last coordinate for the present z level, controller 504 can select the next x, y point at 612. Controller 504 can then, as previously described, send a signal to the drivers which can then move the servos as needed, and again trigger laser 502 at 608. Controller 504 can continue to move laser 502 to each x, y point for the present z-level.

Otherwise, if controller 504 determines at 610 that an x, y point at 610 is the last coordinate for the present z level, controller 504 can determine if the present z level is the final focal depth to be etched at 614. If controller 504 determines that the present z level is not the final depth to be etched at 614, then controller 504 can select the next z level at 616. Then, at 606, an x, y point for the new z level can be selected. Controller 504 can continue to move laser 502 to each x, y point for the new z level. Furthermore, controller 504 can continue to move laser 502 to a new z level after completing all x, y points selected for the particular z level. Alternatively, if controller 504 determines at 614 that the lowest z level or any other z level is the last level to be etched, controller 504 can end the process at 618.

It should be understood that some of the above steps of process 600 of FIG. 6 may be executed or performed in an order or sequence other than the order and sequence shown and described in the figure. Also, some of the above steps of process 600 may be executed or performed substantially simultaneously where appropriate or in parallel to reduce latency and processing times.

SSLE can be used in several applications. For example, SSLE can be used in the fabrication of solar cells. SSLE can be used in processes for fabricating heterojunction solar cells with a machine for amorphous silicon deposition of 6 inch square standard industrial size substrates.

In some embodiments, controller 504 can be any of a general purpose device such as a computer or a special purpose device such as a client, a server, etc. Any of these general or special purpose devices can include any suitable components such as a hardware processor (which can be a microprocessor, digital signal processor, a controller, etc.), memory, communication interfaces, display controllers, input devices, etc. In some embodiments, memory can include a storage device (such as a non-transitory computer-readable medium) for storing a computer program (which can implement process 600 in some embodiments) for controlling the hardware processor. For example, controller 504 can be implemented as a personal computer, a laptop computer, any other suitable computing device, or any suitable combination thereof.

The hardware processor can use the computer program to present on the display content and/or an interface that allows a user to interact with the mechanisms described herein for using SSLE to create one or more wafers from a material, and to send and receive data through a communications link. It should also be noted that data received through the communications link or any other communications links can be received from any suitable source. In some embodiments, the hardware processor can send and receive data through the communications link or any other communication links using, for example, a transmitter, receiver, transmitter/receiver, transceiver, or any other suitable communication device. The input device can be a computer keyboard, a computer mouse, a touchpad, a voice recognition circuit, a touchscreen, and/or any other suitable input device.

In some embodiments, any suitable computer readable media can be used for storing instructions for performing the processes described herein. For example, in some embodiments, computer readable media can be transitory or non-transitory. For example, non-transitory computer readable media can include media such as magnetic media (such as hard disks, floppy disks, etc.), optical media (such as compact discs, digital video discs, Blu-ray discs, etc.), semiconductor media (such as flash memory, electrically programmable read only memory (EPROM), electrically erasable programmable read only memory (EEPROM), etc.), any suitable media that is not fleeting or devoid of any semblance of permanence during transmission, and/or any suitable tangible media. As another example, transitory computer readable media can include signals on networks, in wires, conductors, optical fibers, circuits, any suitable media that is fleeting and devoid of any semblance of permanence during transmission, and/or any suitable intangible media.

Although the invention has been described an illustrated in the foregoing illustrative embodiments, it is understood that the present disclosure has been made only by way of example, and that numerous changes in the details of implementation of the invention can be made without departing from the spirit and scope of the invention, which is only limited by the claim which follows. Features of the disclosed embodiments can be combined and rearranged in various ways.

1. A method for using SSLE to create one or more wafers from a material, comprising:
using a laser Sight beam to etch pits in the material to create one or more layers of etch pits in a subsurface of the material; and
dividing the material into one or more individual wafers with an etch.

2. The method of claim 1, wherein the laser light beam has a wavelength of between about 1 μm and about 2 μm.

3. The method of claim 1, wherein the material is transparent to the laser light beam at some intensities and absorbs the laser light beam at other intensities.

4. The method of claim 1, wherein the laser light beam has an intensity over 1×10⁶ W/cm².

5. The method of claim 1, wherein the one or more wafers are cut to a thickness between about 10 μm to about 200 μm.

6. The method of claim 1, wherein the laser light beam creates etch pits between about 10 microns to about 1 mm apart.

7. A system for using SSLE to create one or more wafers from a material comprising:
a controller for controlling the position of a focal point of a laser light beam with respect to the material and causing an irradiation of the laser light beam at a plurality of focal points; and
an etch for splitting the material into the one or more wafers based on the plurality of focal points.

8. The system of claim 7, wherein the laser light beam has a wavelength of between about 1 μm to about 2 μm.

9. The system of claim 7, wherein the material is transparent to the laser light beam at some intensities and absorbs the laser light beam at other intensities.

10. The system of claim 7, wherein the laser light beam has an intensity over 1×10⁶ W/cm².

11. The system of claim 7, wherein the controller causes the plurality of focal points to define wafers of about 10 μm about 200 μm.

12. The system of claim 7, wherein the controller causes laser light beam creates etch pits between about 10 microns to about 1 mm apart.
